(19) United States
(12) Patent Application Publication
(10) Pub. No.: US 2023/0407479 A1
(43) Pub. Date: Dec. 21, 2023

(54) SUBSTRATE HOLDER, SUBSTRATE PROCESSING APPARATUS, METHOD OF MANUFACTURING SEMICONDUCTOR DEVICE AND RECORDING MEDIUM

(71) Applicant: Kokusai Electric Corporation, Tokyo (JP)

(72) Inventors: Yusaku OKAJIMA, Toyama-shi (JP); Takatomo YAMAGUCHI, Toyama-shi (JP)

(73) Assignee: Kokusai Electric Corporation, Tokyo (JP)

(21) Appl. No.: 18/458,491

(22) Filed: Aug. 30, 2023

Related U.S. Application Data
(63) Continuation of application No. PCT/JP2021/011527, filed on Mar. 19, 2021.

(51) Int. Cl. C23C 16/458

(52) U.S. Cl. CPC C23C 16/4586

(57) ABSTRACT

There is provided a technique including: a substrate support including a plurality of first props capable of supporting a plurality of substrates at intervals in an up-down direction; and a partition support including a plurality of partitions and a plurality of second props, the plurality of partitions each having a cut-away portion at which the plurality of first props is disposed, the plurality of partitions being disposed one-to-one in spaces between the plurality of substrates held by the substrate support, the plurality of second props supporting the plurality of partitions.

### CROSS-REFERENCES

This application is a Bypass Continuation application of PCT International Application No. PCT/JP2021/011527, filed on Mar. 19, 2021, the entire contents of which are incorporated herein by reference.

### BACKGROUND OF THE INVENTION

The present disclosure relates to a substrate holder, a substrate processing apparatus, a method of manufacturing a semiconductor device and a recording medium.

### DESCRIPTION OF RELATED ART

For substrate (wafer) processing in a process of manufacturing a semiconductor device, a substrate holder holds a plurality of substrates in a vertical array, and then the substrate holder is loaded into a process chamber. After that, processing gas is introduced into the process chamber, followed by thin-film forming processing to the substrates.

### SUMMARY OF THE INVENTION

The present disclosure is directed to providing a technique enabling, in simultaneous processing to a plurality of substrates, an improvement in the uniformity of thickness of a film to be formed on each substrate.

According to an embodiment of the present disclosure, there is provided a technique including:
a substrate support including a plurality of first props capable of supporting a plurality of substrates at intervals in an up-down direction; and
a partition support including a plurality of partitions and a plurality of second props, the plurality of partitions each having a cut-away portion at which the plurality of first props is disposed, the plurality of partitions being disposed one-to-one in spaces between the plurality of substrates held by the substrate support, the plurality of second props supporting the plurality of partitions.

### BRIEF DESCRIPTION OF THE DRAWINGS

FIG. 1 is a schematic sectional view of a process chamber and a housing chamber with a boat on which substrates are placed, loaded in a transfer chamber, in a substrate processing apparatus according to a first embodiment of the present disclosure.

FIG. 2 is a schematic sectional view of the process chamber and the housing chamber with the boat on which the substrates are placed, loaded in the process chamber due to rising, in the substrate processing apparatus according to the first embodiment of the present disclosure.

FIG. 3A is a perspective view of a configuration for lateral insertion of a partition to the props (support rods) of the boat, in the substrate processing apparatus according to the first embodiment of the present disclosure.

FIG. 3B is a plan view of the partition in FIG. 3A.

FIG. 4A is a perspective view of a configuration for downward insertion of the props (support rods) of the boat to a partition, in the substrate processing apparatus according to the first embodiment of the present disclosure.

FIG. 4B is a plan view of the partition in FIG. 4A.

FIG. 4C is a perspective view of a partition support including such partitions as in FIG. 4A and having the boat incorporated therein.

FIG. 4D is a plan view for the relationship between a substrate holder and a partition with the partition support including such partitions as in FIG. 4A and having the boat incorporated therein.

FIG. 5A is a perspective view of an assembly configuration for lateral insertion of the props (support rods) of the boat to a partition, in the substrate processing apparatus according to the first embodiment of the present disclosure.

FIG. 5B is a plan view of the partition in FIG. 5A.

FIG. 6 is a perspective view of an inner reaction tube in the substrate processing apparatus according to the first embodiment of the present disclosure.

FIG. 7 is a front view of a gas supply nozzle.

FIG. 8 is a sectional view of the partition support and the boat with a cover, which covers the lower portion of the partition support, incorporated in the partition support.

FIG. 9 is a perspective view of the cover, which covers the lower portion of the partition support.

FIG. 10 is a perspective view of a prop (support rod) of the boat for use with the partition support in which the cover is incorporated.

FIG. 11 is a sectional view for the relationship between the props (support rods) of the boat and the cover with the partition support in which the cover is incorporated.

FIGS. 12A to 12C are sectional views of a substrate and partitions in the process chamber of the substrate processing apparatus according to the first embodiment of the present disclosure, in which the interval between the substrate and either partition is illustrated.

FIG. 13 is a graph indicating distributions of concentration of material gas on the surface of a substrate with a change in the interval between each substrate and the corresponding partition in the process chamber of the substrate processing apparatus according to the first embodiment of the present disclosure.

FIG. 14 illustrates a visualized distribution of concentration of material gas on the surface of a substrate in the process chamber of the substrate processing apparatus according to the first embodiment of the present disclosure and is a perspective view of a substrate with the distribution of concentration of material gas on the surface of the substrate in a case where the interval between each substrate and the corresponding partition is set wide as illustrated in FIG. 3C.

FIG. 15 is a block diagram of an exemplary configuration of a controller of the substrate processing apparatus according to the first embodiment of the present disclosure.

FIG. 16 is a schematic flowchart of a process of manufacturing a semiconductor device according to the first embodiment of the present disclosure.

FIG. 17 is a table of a list of items in an exemplary process recipe that a CPU reads in the substrate processing apparatus according to the first embodiment of the present disclosure.

FIG. 18 is a schematic sectional view of a schematic configuration of a substrate processing apparatus according to a second embodiment of the present disclosure.

FIG. 19 is a schematic sectional view of a schematic configuration of a substrate processing apparatus according to a third embodiment of the present disclosure.

FIG. 20 is a schematic sectional view of a schematic configuration of a substrate processing apparatus according to a fourth embodiment of the present disclosure.

### DETAILED DESCRIPTION

The present disclosure relates to a substrate holder including: a substrate support including a plurality of first props capable of supporting a plurality of substrates at intervals in an up-down direction; and a partition support including a plurality of partitions and a plurality of second props, the plurality of partitions each having a cut-away portion at which the plurality of first props is disposed, the plurality of partitions being disposed one-to-one in spaces between the plurality of substrates held by the substrate support, the plurality of second props supporting the plurality of partitions, in which the gap between each of the plurality of first props and the cut-away portion of each partition causes no contact with the cut-away portion even when the plurality of first props moves upward or downward and has a size such that gas is inhibited from flowing to the upper side or lower side of the partition. Thus, the substrate holder enables film forming with high-accuracy control to the plurality of substrates held at regular intervals in the up-down direction by the substrate support.

In addition, the present disclosure relates to a substrate processing apparatus including: a boat capable of bearing a plurality of substrates; a partition support independent from the boat, the partition support including a plurality of partitions and a support supporting the plurality of partitions, the plurality of partitions being disposed one-to-one in respective upper spaces of the plurality of substrates placed on the boat; a first lifter that lifts the boat up or down; and a second lifter that causes a change in the positional relationship in an up-down direction between the plurality of substrates and the plurality of partitions.

Embodiments of the present disclosure will be described in detail below based on the drawings. In all figures for describing the embodiments of the present disclosure, constituents having the same functions are denoted with the same reference signs and thus duplicate description thereof will be omitted in principle.

Note that the present disclosure should not be construed as being limited to the following embodiments. It is obvious to those skilled in the art that the specific configurations can be modified without departing from the idea or spirit of the present disclosure. Note that the drawings used in the following description are all schematic and thus, for example, the dimensional relationship between each constituent element and the ratio between each constituent element illustrated in the drawings do not necessarily coincide with realities. In addition, for example, a plurality of drawings does not necessarily coincide with each other in the dimensional relationship between each constituent element or in the ratio between each constituent element.

### First Embodiment of the Present Disclosure

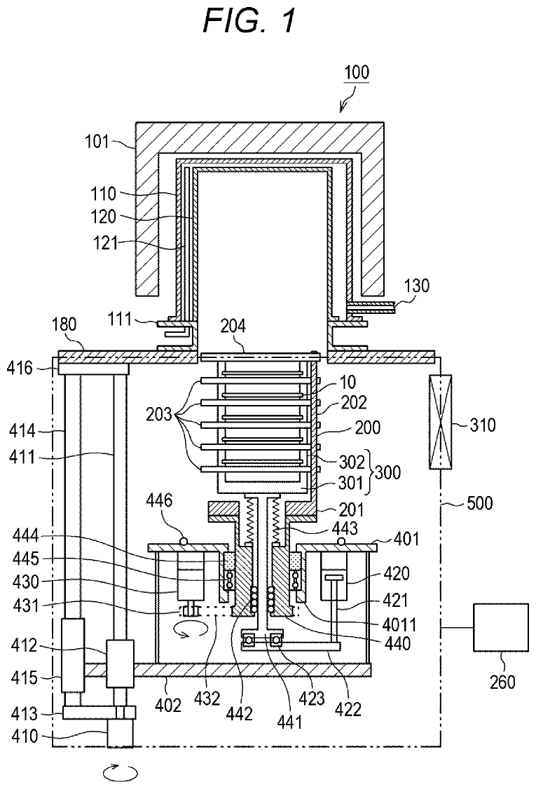

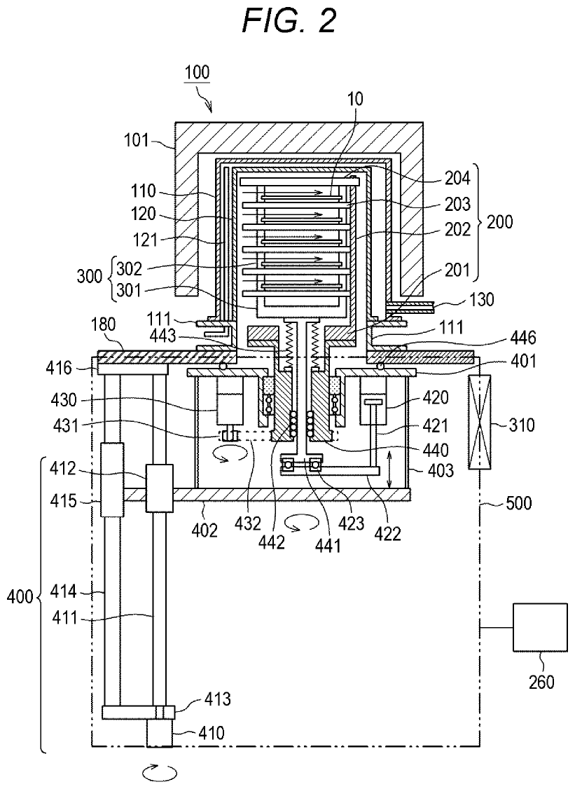

The configuration of a substrate processing apparatus according to a first embodiment of the present disclosure will be described with FIGS. 1 and 2.

[Substrate Processing Apparatus 100]

A substrate processing apparatus 100 includes an outer reaction tube 110 and an inner reaction tube 120 that are cylindrical in shape and extend vertically, a heater 101 serving as a furnace body provided along the outer circumference of the outer reaction tube 110, and a gas supply nozzle 121 corresponding to a gas supplier. The heater 101 corresponds to a zone heater having a plurality of blocks divided in the up-down direction and enabling temperature setting per individual block.

The outer reaction tube 110 and the inner reaction tube 120 are each formed of a material, such as quartz or SiC. The outer reaction tube 110 is connected to an exhauster (not illustrated) through an exhaust pipe 130 corresponding to an exhaust, and thus the atmosphere inside the outer reaction tube 110 and the atmosphere inside the inner reaction tube 120 are exhausted by the exhauster (not illustrated). The outer reaction tube 110 is hermetically sealed by a gasket (not illustrated) such that its inside is not exposed to the open air.

The outer reaction tube 110 and the inner reaction tube 120 are disposed coaxially. The gas supply nozzle 121 is disposed between the outer reaction tube 110 and the inner reaction tube 120.

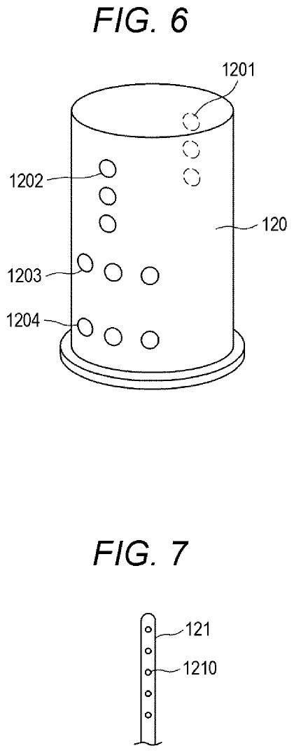

As illustrated in FIG. 7, the gas supply nozzle (hereinafter, also simply referred to as a nozzle) 121 has many holes 1210 for supplying gas from between the outer reaction tube 110 and the inner reaction tube 120 into the inner reaction tube 120. As illustrated in FIG. 6, the inner reaction tube 120 has gas introduction holes 1201 located opposite the holes 1210 with which the gas supply nozzle 121 is provided.

Source gas, reactant gas, and inert gas (carrier gas) supplied from the holes 1210 of the gas supply nozzle 121 are introduced into the inner reaction tube 120 through the gas introduction holes 1201 of the inner reaction tube 120.

The source gas, reactant gas, and inert gas (carrier gas), respectively, from a source-gas supply source (not illustrated), a reactant-gas supply source (not illustrated), and an inert-gas supply source (not illustrated) are each regulated in flow rate by a mass flow controller (MFC) (not illustrated) and then are each supplied from the holes 1210 of the nozzle 121 into the inner reaction tube 120 through the gas introduction holes 1201.

The gas having not contributed to reaction inside the inner reaction tube 120 among the source gas, reactant gas, and inert gas (carrier gas) supplied into the inner reaction tube 120 flows in between the inner reaction tube 120 and the outer reaction tube 110 through exhaust holes 1203 and 1204 (hereinafter, also simply referred to as holes 1203 and 1204) located opposite the gas introduction holes 1201 of the inner reaction tube 120, and then is exhausted outward from the outer reaction tube 110 through the exhaust pipe 130 of the outer reaction tube 110 by the exhauster (not illustrated).

[Chamber 180]

A chamber 180 is provided below the outer reaction tube 110 and the inner reaction tube 120 through a manifold 111 and includes a housing chamber 500. In the housing chamber 500, through a substrate access port 310, a substrate 10 is placed (mounted) on a substrate support (boat) 300 by a transferer (not illustrated) or the substrate 10 is taken from the substrate support (hereinafter, also simply referred to as a boat) 300 by the transferer.

The chamber 180 is formed of a metal material, such as stainless steel (SUS) or aluminum (Al).

Inside the chamber 180, provided are the substrate support 300, a partition support 200, and an upward/downward movement driver 400 corresponding to a first driver that drives the substrate support 300 and the partition support 200 (collectively referred to a substrate holder) upward/downward or rotationally.

[Substrate Support]

A substrate support includes at least the substrate support (boat) 300. Inside the housing chamber 500, a substrate 10 is translocated to the substrate support by the transferer (not illustrated) through the substrate access port 310. The translocated substrate 10 is transferred into the inner reaction tube 120, followed by processing of forming a thin film on the surface of the substrate 10. Note that the substrate support may include the partition support 200.

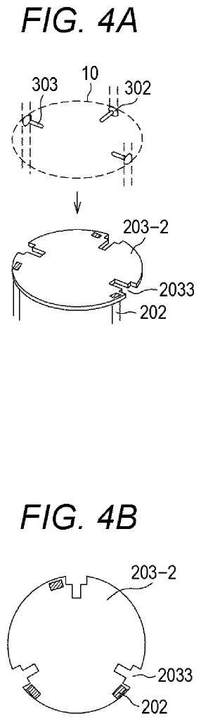

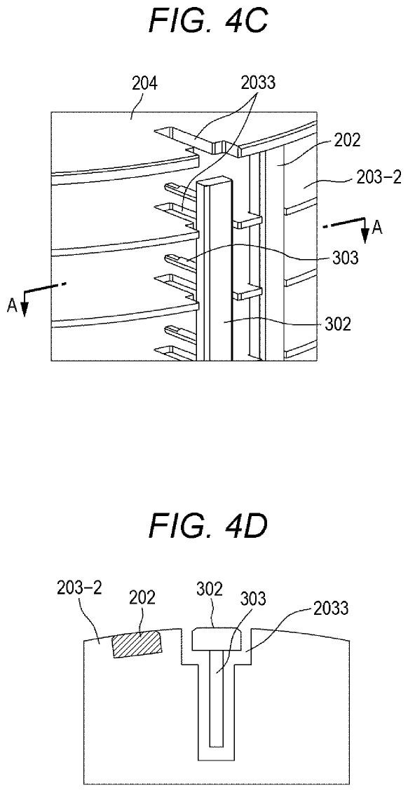

As illustrated in FIGS. 1 and 2, the partition support 200 includes a base 201, a top 204, a prop 202 serving as a second prop supported between the base 201 and the top 204, and a plurality of partitions 203 that is discoid in shape and is fixed at predetermined pitches to the prop 202. As illustrated in FIGS. 1 and 2, the substrate support 300 includes a base 301 and a plurality of support rods 302 each serving as a first prop supported by the base 301, in which the plurality of support rods 302 each has substrate holders 303 serving as supports attached thereto at regular pitches (refer to FIG. 4C), and a plurality of substrates 10 is supported at predetermined intervals by the substrate holders 303.

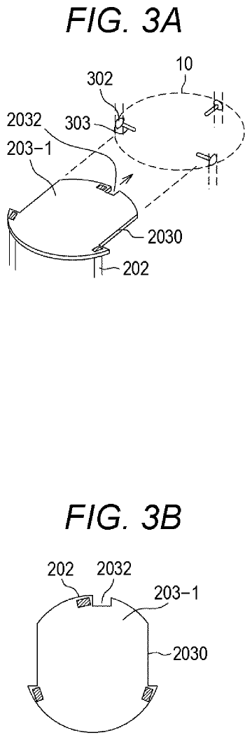

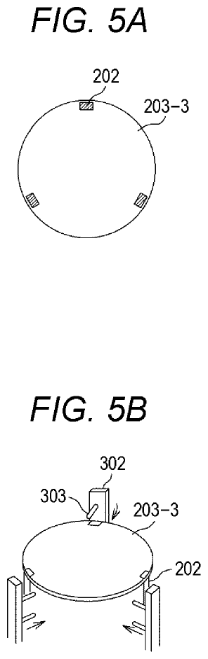

Between each of the plurality of substrates 10 supported by the substrate holders 303 attached to the support rods 302, interposed is one of the partitions 203 discoid in shape fixed (supported) at predetermined intervals to the prop 202 supported by the partition support 200 (corresponding to a partition 203-1 in FIG. 3B, a partition 203-2 in FIG. 4B, or a partition 203-3 in FIG. 5B). Such a partition 203 is disposed either above or below a substrate 10 or such partitions 203 are disposed one-to-one above and below a substrate 10.

The predetermined interval between each of the plurality of substrates 10 placed on the substrate support 300 is identical to the vertical interval between each of the partitions 203 fixed to the partition support 200. The partitions 203 are larger in diameter than the substrates 10.

The boat 300 supports, through the plurality of support rods 302, a plurality of substrates 10, such as five substrates 10, on a multiple-stage basis in the vertical direction. The vertical interval between each of the substrates 10 supported on a multiple-stage basis in the vertical direction is set at, for example, approximately 60 mm. The base 301 and the plurality of support rods 302 included in the boat 300 are each formed of a material, such as quartz or SiC. Note that an example in which the boat 300 supports five substrates 10 will be given herein, but this is not limiting. For example, provided may be a boat 300 capable of supporting substrates 10 of which the number is 5 to 50. Note that each partition 203 of the partition support 200 is also called a separator.

The upward/downward movement driver 400 drives the partition support 200 and the substrate support 300 upward/downward between the inner reaction tube 120 and the housing chamber 500 or rotationally around the center of the substrates 10 supported by the substrate support 300.

As illustrated in FIGS. 1 and 2, the upward/downward movement driver 400 corresponding to the first driver includes, as drive sources, an upward/downward drive motor 410, a rotation drive motor 430, and a boat elevator 420 including a linear actuator serving as a substrate-support lifter that drives the substrate support 300 upward/downward.

The upward/downward drive motor 410 serving as a partition-support lifter drives a ball screw 411 rotationally, so that a nut 412 screwed with the ball screw 411 moves upward/downward along the ball screw 411. Thus, the partition support 200 and the substrate support 300 are driven upward/downward between the inner reaction tube 120 and the housing chamber 500 together with a base plate 402 to which the nut 412 is fixed. The base plate 402 is fixed to a ball guide 415 engaged with a guide shaft 414 and thus is smoothly movable upward/downward along the guide shaft 414. The ball screw 411 has an upper end portion and a lower end portion fixed to fixation plates 416 and 413, respectively. The guide shaft 414 has an upper end portion and a lower end portion fixed to the fixation plates 416 and 413, respectively. Note that the partition-support lifter may include a transmission that transmits the power of the upward/downward drive motor 410.

The rotation drive motor 430 and the boat elevator 420 including the linear actuator correspond to a second driver and are fixed to a base flange 401 serving as a lid supported to the base plate 402 through a side plate 403. The use of the side plate 403 enables inhibition of dispersion of particles, for example, from the elevator or rotator. The covering shape is tubular or columnar. Part of the covering shape or the bottom face is provided with a hole in communication with a transfer chamber. Due to the hole in communication, the covering shape has its inside at a pressure similar to the pressure inside the transfer chamber.

Alternatively, instead of the side plate 403, props may be used. In this case, the elevator or rotator is maintained easily.

The rotation drive motor 430 has a leading end portion to which a gear 431 is attached and drives a rotation transmission belt 432 engaged with the gear 431, so that a support 440 engaged with the rotation transmission belt 432 is driven rotationally. The support 440 supports the partition support 200 through the base 201. Thus, the rotation drive motor 430 drives the support 440 through the rotation transmission belt 432, resulting in rotation of the partition support 200 and the boat 300.

Between the support 440 and an inner portion 4011 of the barrel of the base flange 401, a vacuum seal 444 is interposed. The vacuum seal 444 has a lower portion guided rotatably by a bearing 445 with respect to the inner portion 4011 of the barrel of the base flange 401.

The boat elevator 420 including the linear actuator drives a shaft 421 upward/downward. The shaft 421 has a leading end portion to which a plate 422 is attached. The plate 422 is connected to a support 441 fixed to the base 301 of the boat 300 through a bearing 423. Since the support 441 is connected to the plate 422 through the bearing 423, the boat 300 can rotate together with the partition support 200 when the rotation drive motor 430 drives the partition support 200 rotationally.

Meanwhile, the support 441 is supported by the support 440 through a linear guide bearing 442. According to such a configuration, when the boat elevator 420 including the linear actuator drives the shaft 421 upward/downward, the support 441 fixed to the boat 300 can be driven upward/downward, relative to the support 440 fixed to the partition support 200.

Such a configuration in which the support 440 and the support 441 are concentric as above enables a simple structure of the rotator with the rotation drive motor 430. In addition, control of synchronization in rotation is facilitated between the boat 300 and the partition support 200.

Note that the present first embodiment is not limited to this, and thus the support 440 and the support 441 may be disposed separately, instead of being concentric.

A vacuum bellows 443 is interposed as a connection between the support 440 fixed to the partition support 200 and the support 441 fixed to the boat 300.

The base flange 401 serving as a lid has an upper face provided with a vacuum-sealing O-ring 446. As illustrated in FIG. 2, when the upper face of the base flange 401 is pressed against the chamber 180 after rising due to driving of the upward/downward drive motor 410, the outer reaction tube 110 has its inside kept airtight.

Note that the vacuum-sealing O-ring 446 is not necessarily provided and thus pressing the upper face of the base flange 401 against the chamber 180 without the vacuum-sealing O-ring 446 may cause the outer reaction tube 110 to have its inside kept airtight. Furthermore, the vacuum bellows 443 is not necessarily provided.

Note that, referring to FIGS. 1 and 2, an exemplary reaction tube having a double structure including the outer reaction tube 110 and the inner reaction tube 120 is given, but a configuration including the outer reaction tube 110 with no inner reaction tube may be given. The following description is given based on a configuration including the outer reaction tube 110 and the inner reaction tube 120 as illustrated in FIGS. 1 and 2.

In the example illustrated in FIGS. 1 and 2, given is the configuration in which the gas supply nozzle 121 is disposed extending in the longitudinal direction in FIGS. 1 and 2 between the outer reaction tube 110 and the inner reaction tube 120. However, the gas supply nozzle 121 may be disposed extending horizontally along the side face of the inner reaction tube 120. Alternatively, a plurality of nozzles may be inserted laterally (horizontally to substrates 10) to supply gas to the plurality of substrates 10 in one-to-one correspondence.

[Partition Support]

In the present first embodiment, for a structure enabling a variable interval between each partition 203 of the partition support 200 and the corresponding substrate 10, the partition support 200 and the substrate support 300 are independent from each other. In addition, either the partition support 200 or the substrate support 300 or both thereof are drivable upward/downward (variable). Thus, provided is a reaction furnace enabling regulation of the distribution of film thickness of a thin film to be formed on the surface of each substrate 10 with a change in the interval between each substrate 10 and the corresponding partition 203.

For the partition support 200 and the substrate support 300 that move relatively upward/downward, prevention of interference is needed between the partitions 203 of the partition support 200 and the support rods 302 and substrate holders 303 of the substrate support 300.

FIGS. 3A and 3B illustrate the shape of a partition 203-1 in a configuration for lateral incorporation of a partition support 200 into a substrate support 300 after the partition support 200 and the substrate support 300 are separately assembled. As illustrated in FIG. 3A, the partition support 200 is incorporated laterally into the substrate support 300. In this case, as illustrated in FIG. 3B, the partition 203-1 has cut-away portions 2030 and 2032 in order to avoid interference with any support rod 302 or substrate holder 303 of the substrate support 300.

On the other hand, FIGS. 4A to 4D illustrate a configuration for downward incorporation of a substrate support 300 into a partition support 200. FIG. 4A illustrates a state of downward incorporation of the substrate support 300 into the partition support 200 from above. For such incorporation, as illustrated in FIG. 4B, in order to avoid interference with any support rod 302 or substrate holder 303 of the substrate support 300, a partition 203-2 has a plurality of cut-away portions 2033 of which the shapes are similar to that of a support rod 302 and a substrate holder 303 projected from directly above.

That is, each cut-away portion 2033 of such a partition 203-2 as illustrated in FIGS. 4A to 4D includes, in addition to a cutaway serving as a first recess for avoidance of interference with a support rod 302, a cutaway serving as a second recess for avoidance of interference with a substrate holder 303 (that is, such that a substrate holder 303 can be housed).

FIG. 4C is a perspective view of the partition support 200 in which the substrate support 300 has been incorporated. The top 204 and partitions 203-2 included in the partition support 200 each have cut-away portions 2033.

FIG. 4D is a sectional view taken along line A-A of FIG. 4C. Each cut-away portion 2033 of such a partition 203-2 is larger by 2 to 4 mm in dimensions than a support rod 302 and a substrate holder 303 projected from directly above. In a case where the difference in dimensions is smaller than 2 mm, the partition 203-2 is likely to come in contact with any of the support rods 302 or any of the substrate holders 303. On the other hand, in a case where the difference in dimensions is larger than 4 mm, an increase in the upward or downward outflow rate/inflow rate of gas through the gap between the partition 203-2 and each support rod 302 or each substrate holder 303 causes a turbulent flow of gas, leading to turbulence in a flow of gas controlled on the surface of the substrate held by the substrate holders 303. The gap having a size of 2 to 4 mm enables, with the partition 203-2 in no contact with any support rod 302 or substrate holder 303, inhibition of turbulence in a flow of gas controlled on the surface of the substrate 10.

Such a dimensional relationship between each cut-away portion 2033 and each support rod 302 as above enables a small cross section of the gas flow path between the partition 203-2 and each support rod 302. Thus, a small inflow/outflow of gas can be made between the upper and lower spaces of the partition 203-2, so that a flow of gas can be controlled accurately on the surface of the substrate 10 held by the substrate holders 303.

FIGS. 5A and 5B illustrate, in a configuration for outside-in incorporation of the support rods 302 of a substrate support 300 with a partition support 200, the relationship between the partition support 200 and the substrate support 300. As illustrated in FIG. each support rod 302 having substrate holders 303 attached thereto is incorporated with the partition support 200 from outside and then is fixed to the base 301 of such a boat 300 as illustrated in FIG. 1 or 2.

According to such a configuration, when a support rod 302 is incorporated with the partition support 200 from outside, the support rod 302 can be prevented from interfering with the partition support 200. As a result, as illustrated in FIG. 5B, a partition 203-3 does not need to have a cut-away portion for avoidance of interference with a substrate holder 303 or a support rod 302. Note that, in a case where a support rod 302 interferes with such a partition 203-3, the partition 203-3 may have a cut-away portion for avoidance of interference with the support rod 302.

As illustrated in FIG. 6, the inner reaction tube 120 has many gas introduction holes 1201 arrayed linearly longitudinally at its upper portion, many gas discharge holes 1202 located opposite the gas introduction holes 1201, a plurality of gas discharge holes 1203 arrayed laterally at its intermediate portion below the gas discharge holes 1202, and a plurality of gas discharge holes 1204 arrayed laterally at its lower portion.

Among the holes, the gas introduction holes 1201 arrayed linearly longitudinally at the upper portion serve as gas supply holes, located opposite the holes 1210 of the gas supply nozzle 121 illustrated in FIG. 7, for introducing the gas supplied from the holes 1210 of the gas supply nozzle 121 into the inner reaction tube 120.

The gas discharge holes 1202 located opposite the gas introduction holes 1201 arrayed linearly longitudinally at the upper portion serve as holes for discharging, outward from the inner reaction tube 120, the gas having not contributed to reaction on the surface of each substrate 10 in the gas introduced from the holes 1210 of the nozzle 121 into the inner reaction tube 120.

The plurality of gas discharge holes 1203 arrayed laterally at the intermediate portion serves as holes for discharging, outward, the gas flowing lower than the holes 1202 inside the inner reaction tube 120 in the gas having not contributed to reaction on the surface of each substrate 10.

Due to the provision of the plurality of gas discharge holes 1203 at the intermediate portion of the inner reaction tube 120, film-forming gas supplied inside the inner reaction tube 120 is discharged into the space between the inner reaction tube 120 and the outer reaction tube 110, so that an inflow can be inhibited to a heat insulator (metal furnace opening) (not illustrated) disposed at the lower portion of the inner reaction tube 120. Preferably, the plurality of gas discharge holes 1203 at the intermediate portion of the inner reaction tube 120 is disposed at the height at which the spatial temperature inside the inner reaction tube 120 is 300° C. or more. In addition, preferably, most of the plurality of gas discharge holes 1203 is allocated opposite the exhaust pipe 130 with which the outer reaction tube 110 is provided.

Meanwhile, the plurality of gas discharge holes 1204 arrayed laterally at the lower portion serves as holes for discharging, from the inner reaction tube 120, the purge gas (e.g., N₂ gas) supplied from a purge-gas supplier (not illustrated) into the inner reaction tube 120 in order to prevent the gas introduced inside the inner reaction tube 120 through the holes 1201 arrayed linearly longitudinally at the upper portion from flowing toward a driver that drives the base 201 of the partition support 200 and the base 301 of the boat 300.

Such a partition 203-2 as illustrated in FIGS. 4A to 4D has cut-away portions 2033. Thus, through the gap between the partition 203-2 and each support rod 302 or each substrate holder 303, purge gas for purging the metal furnace opening (not illustrated) on the lower side of the inner reaction tube 120 or the inside of a cover 220 (refer to FIG. 9) flows into a wafer film-forming section inside the inner reaction tube 120. Against this, as illustrated in FIG. 6, the provision of the plurality of gas discharge holes 1204 at the lower portion of the side face of the inner reaction tube 120 enables inhibition of the purge gas from flowing into the wafer film-forming section inside the inner reaction tube 120. Preferably, the plurality of gas discharge holes 1204 at the lower portion of the side face of the inner reaction tube 120 is disposed equivalently in height to a cut-away portion 222 (refer to FIG. 9) serving as an opening on the lower side of the cover 220 (refer to FIG. 9). Furthermore, preferably, most of the plurality of gas discharge holes 1204 is allocated opposite the exhaust pipe 130 with which the outer reaction tube 110 is provided.

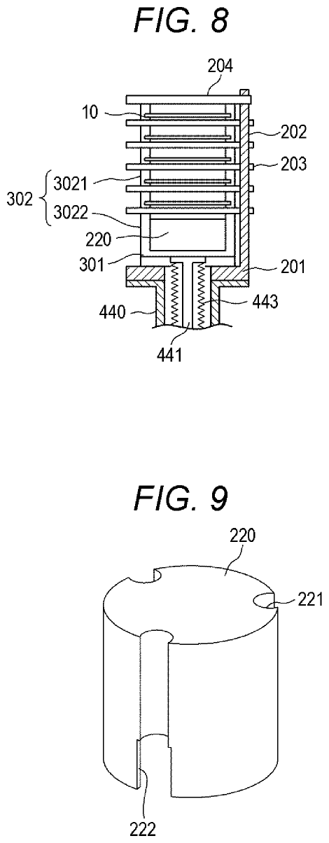

FIG. 8 illustrates a configuration for driving the support rods 302 of the substrate support 300 from the lower side of a cover 220 with which the partition support 200 is provided, in which the cover 220 houses the furnace opening including a heat insulating plate (not illustrated) inside. The support rods 302 each include an upper rod 3021 and a lower rod 3022.

FIG. 9 illustrates the external appearance of the cover 220. The cover 220 has, on its side face, three recesses 221 for avoidance of interference with the support rods 302 of the substrate support 300. Each recess 221 has, at its lower end portion, a cut-away portion 222 for prevention of interference with the base 301 that moves upward/downward in conjunction with the support rods 302. The cut-away portion 222 has a length (dimension in the up-down direction in FIG. 9) including a margin of approximately 1 to mm to an upward end for the base 301 that moves upward/downward. A margin larger than 10 mm is likely to cause processing gas introduced into the inner reaction tube 120 to flow into the cover 220, leading to damage to a heat dissipating plate covered with the cover 220. On the other hand, a margin smaller than 1 mm is likely to cause interference with the base 301.

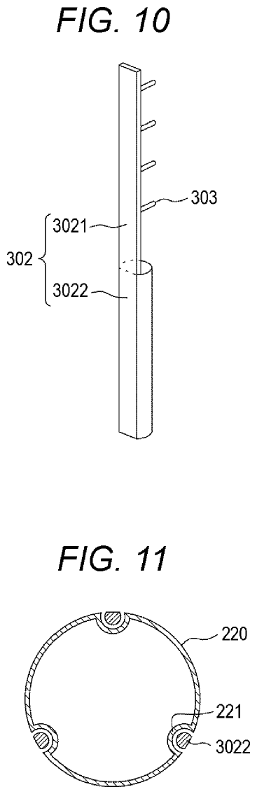

FIG. 10 is a perspective view of a support rod 302. The support rod 302 includes an upper rod 3021 serving as an upper portion and a lower rod 3022 serving as a lower portion. The lower rod 3022 on the lower side opposite the cover 220 has a shape in which the portion facing the cover 220 is columnar in shape and the portion not facing the cover 220 has an outer circumferential face planar in shape (namely, a shape of which the cross section is similar to a semicircle). The upper rod 3021 on the upper side serving as a portion to which substrate holders 303 are attached at regular intervals has a cross section rectangular in shape.

FIG. 11 is a sectional view of the cover 220 having the lower rods 3022 of the support rods 302 incorporated in the recesses 221 on its side face. The recesses 221 each have dimensions to have a gap of approximately 2 to 4 mm to the lower rod 3022 serving as the lower portion of a support rod 302. A gap smaller than 2 mm is likely to cause the lower rod 3022 to come in contact with the recess 221.

In such a configuration as above, as illustrated in FIG. 2, with the substrate support inserted inside the inner reaction tube 120 and with the base flange 401 having its upper face pressed against the chamber 180 after rising due to driving of the upward/downward drive motor 410, source gas, reactant gas, or inert gas (carrier gas) is introduced from the holes 1210 of the gas supply nozzle 121 into the inner reaction tube 120 through the gas introduction holes 1201 of the inner reaction tube 120.

The pitch of the holes 1210 of the gas supply nozzle 121 is identical to the vertical interval between each substrate 10 placed on the boat 300 and the vertical interval between each partition 203 fixed to the partition support 200.

With the base flange 401 having its upper face pressed against the chamber 180, the positions in the height direction of the partitions 203 fixed to the prop 202 of the partition support 200 are fixed, but the positions in the height direction of the substrates supported by the boat 300 can be changed to the partitions 203 by upward/downward movement of the support 441 fixed to the base 301 of the boat 300 due to driving of the boat elevator 420 including the linear actuator. The positions of the holes 1210 of the gas supply nozzle 121 (hereinafter, also simply referred to as the nozzle 121) are also fixed and thus the positions in the height direction of the substrates 10 supported by the boat 300 can be changed to the holes 1210 (relative positions).

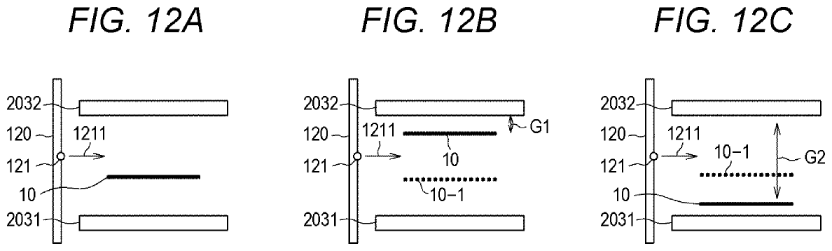

That is, from such as a criterial positional relationship in transfer as illustrated in FIG. 12A, the positions of the substrates 10 supported by the boat 300 are regulated upward/downward due to driving of the boat elevator 420 including the linear actuator, so that the positional relationship with the holes 1210 of the nozzle 121 and the partitions 203 can be changed such that a narrow gap G1 is provided between each substrate 10 and the upper partition 2032 with each substrate 10 of which the position is higher than the transfer position (home position) 10-1 as illustrated in FIG. 12B or such that a wide gap G2 is provided between each substrate 10 and the upper partition 2032 with each substrate 10 of which the position is lower than the transfer position (home position) 10-1 as illustrated in FIG. 12C.

The gas injected from the holes 1210 of the nozzle 121 is supplied to the substrates supported by the boat 300 inside the inner reaction tube 120 through the gas introduction holes 1201 of the inner reaction tube 120. In FIGS. 12A to 12C, for simplification of denotation, no gas introduction holes 1201 (hereinafter, also simply referred to as holes 1201) of the inner reaction tube 120 are displayed.

As above, a change in the positions of the substrates 10 to the holes 1210 of the nozzle 121 can cause a change in the positional relationship between a gas flow 1211 discharged from each hole 1210 and the corresponding substrate 10.

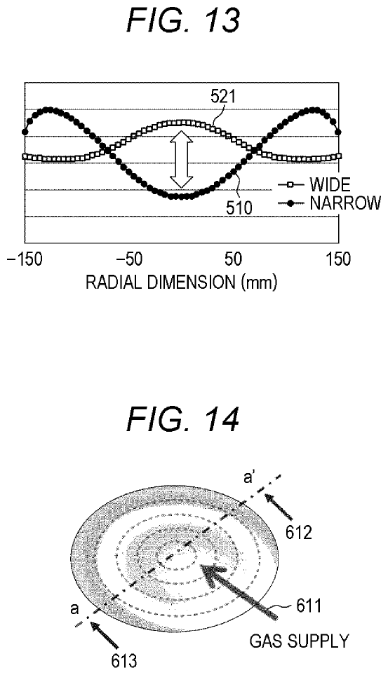

FIG. 13 indicates a simulated result of the in-plane distribution of a film formed on the surface of a substrate 10 in a case where processing gas is supplied from the corresponding hole 1210 of the nozzle 121 with the gap G1 narrow between the substrate at a higher position and the upper partition 2032 as illustrated in FIG. 12B and a simulated result of the in-plane distribution of a film formed on the surface of a substrate in a case where processing gas is supplied from the corresponding hole 1210 of the nozzle 121 with the gap G2 wide between the substrate 10 at a lower position and the upper partition 2032 as illustrated in FIG. 12C.

Referring to FIG. 13, a sequence of points 510 denoted with Narrow results from film forming in such a state as in FIG. 12B, namely, film forming with a substrate 10 higher in position than the gas flow 1211 discharged from the corresponding hole 1210 based on the gap G1 narrow between the substrate 10 at a higher position and the upper partition 2032. In this case, a concave distribution of film thickness is obtained, in which the substrate 10 has a film thicker at its peripheral portion than at its central portion.

In contrast to this, a sequence of points 520 denoted with Wide results from film forming in such a state as in FIG. 12C, namely, film forming with a substrate 10 lower in position than the gas flow 1211 discharged from the corresponding hole 1210 based on the gap G2 wide between the substrate 10 at a lower position and the upper partition 2032. In this case, a convex distribution of film thickness is obtained, in which the substrate 10 has a film thicker at its central portion than at its peripheral portion.

As above, a change in the position of a substrate 10 causes a change in the in-plane distribution of a thin film formed on the surface of the substrate 10.

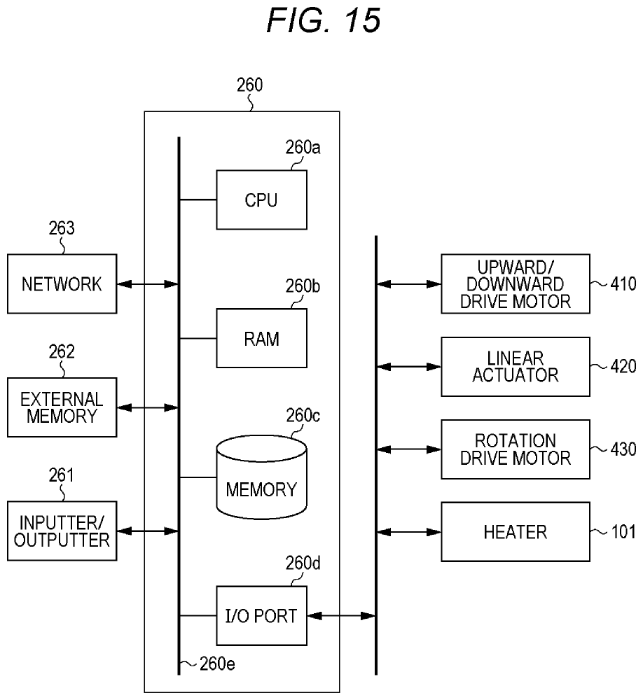

FIG. 14 indicates, in a case where the relationship between the substrate 10, the partition 2032, and the corresponding hole 1210 of the nozzle 121 is set to such a positional relationship as in FIG. 12C, a simulated result of the distribution of partial pressure of processing gas on the surface of the substrate 10 due to supply of processing gas along an arrow 611. Each distribution of film thickness in FIG. 13 corresponds to a distribution of film thickness in a cross section taken along line a-a′ of FIG. 14.

As indicated in FIG. 14, in a case where the relationship between the substrate 10, the partition 2032, and the corresponding hole 1210 of the nozzle 121 is set to such a positional relationship as in FIG. 12C, the partial pressure of processing gas is relatively high in a portion displayed in a bright color ranging from a portion close to the corresponding hole 1210 of the nozzle 121 to the central portion of the substrate 10. Meanwhile, the partial pressure of processing gas is relatively low at the peripheral portion of the substrate 10 away from the corresponding hole 1210 of the nozzle 121.

From such a state, due to rotational driving of the support 440 based on driving of the rotation drive motor 430, the partition support 200 and the boat 300 rotate, that is, the substrates 10 supported by the boat 300 rotate, resulting in reduction of variation in the thickness of a film (distribution of film thickness) in the radial direction of each substrate

[Controller]

As illustrated in FIG. 1, the substrate processing apparatus 100 is connected to a controller 260 that controls the operation of each constituent.

FIG. 15 is a schematic diagram of the controller 260. The controller 260 serves as a computer including a central processing unit (CPU) 260a, a random access memory (RAM) 260b, a memory 260c, and an input/output port (I/O port) 260d. The RAM 260b, the memory 260c, and the I/O port 260d are capable of data exchange with the CPU 260a through an internal bus 260e. An inputter/outputter 261 serving, for example, as a touch panel and an external memory 262 are connectable to the controller 260.

The memory 260c is achieved, for example, with a flash memory, a hard disk drive (HDD), or a solid state drive (SSD). In the memory 260c, readably stored are a control program for controlling the operation of the substrate processing apparatus, a process recipe including procedures of substrate processing and conditions therefor described later, and a database.

Note that the process recipe functions as a program that causes the controller 260 to perform each procedure in a substrate processing process described later to obtain a predetermined result.

Hereinafter, the process recipe and the control program are also collectively and simply referred to as a program. Note that, in the present specification, in some cases, the term “program” indicates only the process recipe, only the control program, or both of the process recipe and the control program. The RAM 260b serves as a memory area (work area) in which the program or data read by the CPU 260a is temporarily stored.

The I/O port 260d is connected to, for example, the substrate access port 310, the upward/downward drive motor 410, the boat elevator 420 including the linear actuator, the rotation drive motor 430, the heater 101, the mass flow controller (not illustrated), a temperature regulator (not illustrated), and a vacuum pump (not illustrated).

Note that the expression “connection” in the present disclosure not only means that each constituent is connected through a physical cable but also means that a signal (electronic data) in each constituent is transmittable/receivable directly or indirectly. For example, a signal relay, a signal converter, or a signal computing unit may be provided between each constituent.

The CPU 260a is capable of reading the control program from the memory 260c to execute the control program and reading the process recipe from the memory 260c in response to an operation command input through the inputter/outputter 261. Then, in accordance with the content of the read process recipe, the CPU 260a is capable of controlling the on/off operation of the substrate access port 310, the driving of the upward/downward drive motor 410, the driving of the boat elevator 420 including the linear actuator, the operation of rotation of the rotation drive motor 430, and the operation of power supply to the heater 101.

Note that the controller 260 may be a dedicated computer or may be a general-purpose computer. For example, the external memory (e.g., a magnetic tape, a magnetic disk, such as a flexible disk or hard disk, an optical disc, such as a CD or DVD, a magneto-optical disc, such as an MO, or a semiconductor memory, such as a USB memory, SSD, or memory card) 262 storing the above program is prepared and then the program is installed on a general-purpose computer through the external memory 262, so that the controller 260 according to the present embodiment can be achieved.

Note that, for supply of the program to a computer, the supply through the external memory 262 is not limiting. For example, the program may be provided through a network 263 (e.g., the Internet or a dedicated line), instead of through the external memory 262. Note that the memory 260c and the external memory 262 each serve as a computer-readable recoding medium. Hereinafter, such memories are collectively and simply referred to as a recording medium. Note that, in the present specification, in some cases, the term “recording medium” indicates only the memory 260c, only the external memory 262, or both thereof.

[Substrate Processing Process (Film-Forming Process)]

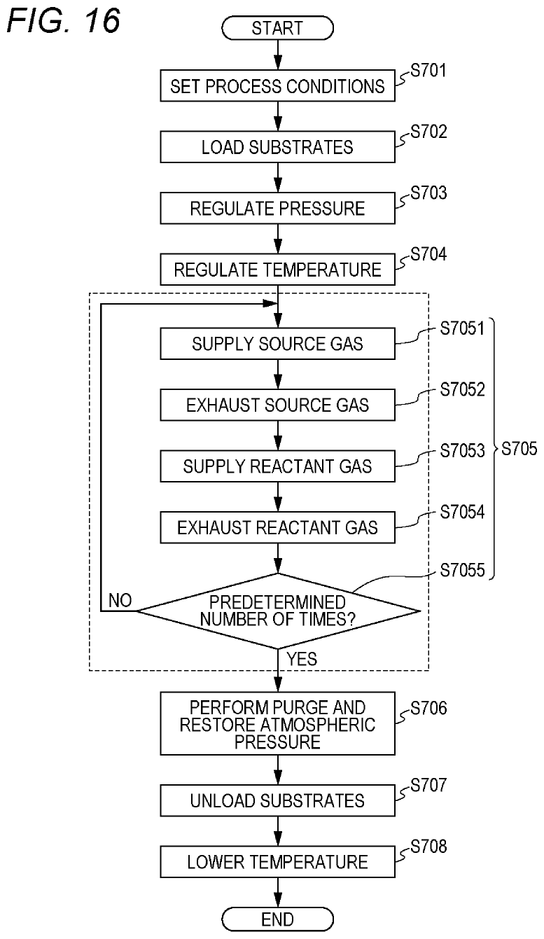

Next, a substrate processing process (film-forming process) in which a film is formed onto a substrate with the substrate processing apparatus described with FIGS. 1 and 2 will be described with FIG. 16.

Although the present disclosure can be applied to both a film-forming process and an etching process, a process of forming a first layer that is an exemplary process of forming a thin film onto a substrate 10 will be described as a partial process in a process of manufacturing a semiconductor device. A process of forming a film, such as the first film, is performed inside the inner reaction tube 120 of the substrate processing apparatus 100 described above. As described above, the CPU 260a of the controller 260 in FIG. 15 executes the program, so that the process of manufacturing a semiconductor device is perform ed.

In the substrate processing process (process of manufacturing a semiconductor device) in the present embodiment, first, the upper face of the base flange 401 is pressed against the chamber 180 after rising due to driving of the upward/downward drive motor 410, so that the substrate support is inserted into the inner reaction tube 120, as illustrated in FIG. 2.

Next, in this state, the boat elevator 420 including the linear actuator drives the shaft 421 upward/downward, so that the height (interval) of each substrate 10 placed on the boat 300 to the corresponding partition 203 is set from the initial state illustrated in FIG. 12A to a state where the interval G1 between the substrate 10 and the corresponding partition 203 is small due to the rise of the substrate 10 as illustrated in FIG. 12B or a state where the interval G2 between the substrate 10 and the corresponding partition 203 is large due to the fall of the substrate 10 as illustrated in FIG. 12C. Thus, the height of each substrate 10 to the corresponding partition 203 (interval between each substrate 10 and the corresponding partition 203) is regulated to a desired value.

In this state,
(a) a step of supplying, from the gas supply nozzle 121, source gas to the substrates housed inside the inner reaction tube 120,
(b) a step of removing the residual gas inside the inner reaction tube 120,
(c) a step of supplying, from the gas supply nozzle 121, reactant gas to the substrates 10 housed inside the inner reaction tube 120, and
(d) a step of removing the residual gas inside the inner reaction tube 120 are repeated a plurality of times to form the first layer on each substrate 10.

During a plurality of times of repetition of the steps (a) to (d) or in the processes (a) and (c), the height (interval) of each substrate 10 to the corresponding partition 203 is periodically switched between the state where the interval G1 between the substrate 10 and the corresponding partition 203 is small due to the rise of the substrate 10 as illustrated in FIG. 12B and the state where the interval G2 between the substrate 10 and the corresponding partition 203 is large due to the fall of the substrate 10 as illustrated in FIG. 12C, while the rotation drive motor 430 is driving, rotationally, the support 440 connected to the rotation drive motor 430 through the rotation transmission belt 432. Thus, a film having a uniform thickness can be formed on each substrate 10.

Note that, in the present specification, in some cases, the term “substrate” means “a substrate itself” or means “a laminate (aggregate) of a substrate and a predetermined layer or film formed on the surface of the substrate” (that is, a substrate and a predetermined layer or film formed on the surface of the substrate are collectively referred to as a substrate). In the present specification, in some cases, the term “surface of a substrate” means “the surface (exposed face) of a substrate itself” or means “the surface of a predetermined layer or film formed on a substrate, namely, the outermost surface of a substrate serving as a laminate”.

Note that, in the present specification, the term “wafer” is synonymous with the term “substrate”.

Next, an exemplary specific film-forming process will be described along a flowchart illustrated in FIG. 16.

(Process Condition Setting): S701

First, the CPU 260a reads the process recipe and a related database stored in the memory 260c to set process conditions. Instead of through the memory 260c, the process recipe and a related database may be acquired through the network.

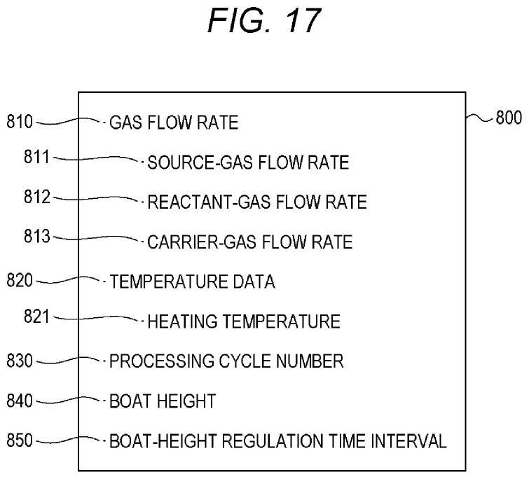

FIG. 17 illustrates an exemplary process recipe 800 that the CPU 260a reads. Examples of main items of the process recipe 800 include gas flow rate 810, temperature data 820, processing cycle number 830, boat height 840, and boat-height regulation time interval 850.

The gas flow rate 810 includes items, such as source-gas flow rate 811, reactant-gas flow rate 812, and carrier-gas flow rate 813. The temperature data 820 includes heating temperature 821 that the heater 101 heats the inside of the inner reaction tube 120 based on.

The boat height 840 includes set values, such as the minimum value (G1) and the maximum value (G2) for the interval between each substrate 10 and the corresponding partition 203 as described with FIGS. 12B and 12C.

The boat-height regulation time interval 850 is for setting the time interval of switching between retention of the interval between each substrate 10 and the corresponding partition 203 at the minimum value as illustrated in FIG. 12B and retention of the interval between each substrate 10 and the corresponding partition 203 at the maximum value as illustrated in FIG. 12C. That is, due to processing with alternate switching of the interval between the surface of each substrate 10 and the corresponding partition 203 (position of each substrate 10 to the position of the corresponding hole 1210 of the gas supply nozzle 121) between the setting as in FIG. 12B and the setting as in FIG. 12C, a thin film is formed on each substrate 10. Thus, a thin film having a flat distribution of film thickness can be formed on the surface of each substrate 10, in which the thickness of the thin film at the central portion and the thickness of the thin film at the peripheral portion are substantially the same.

(Substrate Loading): S702

With the boat 300 housed in the housing chamber 500, new substrates 10 are placed for holding onto the boat 300 on a one-by-one basis through the substrate access port 310 of the housing chamber 500 while the boat 300 is being pitch-fed based on the ball screw 411 driven rotationally due to driving of the upward/downward drive motor 410.

In response to completion of placing of the new substrates 10 onto the boat 300, the substrate access port 310 is shut. Then, with the housing chamber 500 having its inside hermetically sealed to the outside, the boat 300 is raised based on the ball screw 411 driven rotationally due to driving of the upward/downward drive motor 410, followed by loading of the boat 300 from the housing chamber 500 into the inner reaction tube 120.

In this case, the height to which the boat 300 rises due to the upward/downward drive motor 410 is set based on the process recipe read in step S701 such that each position at which gas is blown for supply from the nozzle 121 into the inner reaction tube 120 through the holes 1202 of the tube wall of the inner reaction tube 120 fulfills such a state as illustrated in FIG. 12B or 12C.

(Pressure Regulation): S703

With the boat 300 loaded in the inner reaction tube 120, the inner reaction tube 120 is vacuum-exhausted by the vacuum pump (not illustrated) through the exhaust pipe 130 such that the inner reaction tube 120 is regulated to have its inside at a desired pressure.

(Temperature Regulation): S704

With the inner reaction tube 120 vacuum-exhausted by the vacuum pump (not illustrated), based on the process recipe read in step S701, the heater 101 heats the inside of the inner reaction tube 120 such that the inner reaction tube 120 has its inside at a desired temperature. In this case, the amount of energization to the heater 101 is feedback-controlled based on temperature information detected by a temperature sensor (not illustrated) such that a desired distribution of temperature is acquired inside the inner reaction tube 120. The heating to the inside of the inner reaction tube 120 by the heater 101 continues at least until completion of processing to the substrates 10.

At the time of an elevation in the temperature of the substrates due to heating of the heater 101, the pitch (interval between the back face of each substrate 10 and the lower partition 203 to the substrate 10) is narrowed (the state in FIG. 12C). The narrowed pitch is kept at least until source gas is supplied. After source gas is supplied, the pitch is widened. The pitch may vary between the time of supply of source gas and the time of supply of reactant gas. Furthermore, during supply of source gas (reactant gas), the pitch may vary. Furthermore, the operation timing at which the substrate support and the partition support relatively move upward/downward can be set freely.

[First-Layer Forming Process]: S705

Subsequently, the following detailed steps are performed in order to form the first layer.

(Source Gas Supply): S7051

First, the support 440 is rotated through the rotation transmission belt 432 due to rotational driving of the rotation drive motor 430, so that the partition support 200 and the boat 300 supported by the support 440 rotate.

With the boat 300 kept rotating, source gas having been regulated in flow rate is discharged from the holes 1210 of the nozzle 121. The source gas discharged from the holes 1210 of the nozzle 121 flows into the inner reaction tube 120 through the holes 1201 of the inner reaction tube 120. As above, the source gas having been regulated in flow rate is supplied to the inner reaction tube 120. The gas having not contributed to reaction on the surface of each substrate 10 flows in between the inner reaction tube 120 and the outer reaction tube 110 through the holes 1202 and holes 1203 of the inner reaction tube 120 and then is exhausted through the exhaust pipe 130 of the outer reaction tube 110 by the exhauster (not illustrated).

The boat elevator 420 including the linear actuator operated based on the process recipe read in step S701 drives the shaft 421 upward/downward to move the boat upward and downward at predetermined time intervals, so that the relative position (height) of the surface of each substrate 10 placed on the boat 300 to the corresponding hole 1210 of the nozzle 121 and the corresponding partition 203 of the partition support 200 is switched between a plurality of positions (e.g., between the position illustrated in FIG. 12B and the position illustrated in FIG. 12C).

The source gas discharged from the holes 1210 of the nozzle 121 is introduced into the inner reaction tube 120 through the holes 1201 of the inner reaction tube 120, so that the source gas is supplied to the substrates 10 placed on the boat 300. For example, the flow rate of source gas for supply is set in the range of 0.002 to 1 standard liter per minute (slm), more preferably, in the range of 0.1 to 1 slm.

In this case, inert gas serving as carrier gas is supplied together with the source gas into the inner reaction tube 120. The gas having not contributed to reaction flows in between the inner reaction tube 120 and the outer reaction tube 110 through the holes 1202 and holes 1203 of the inner reaction tube 120 and then is exhausted through the exhaust pipe 130 of the outer reaction tube 110 by the exhauster (not illustrated). Specifically, the flow rate of carrier gas is set in the range of 0.01 to 5 slm, more preferably, in the range of 0.5 to 5 slm.

The carrier gas is supplied into the inner reaction tube 120 through the nozzle 121 and then is exhausted through the exhaust pipe 130. In this case, the temperature of the heater 101 is set such that the temperature of the substrates 10 is, for example, within the range of 250 to 550° C.

The gas flowing into the inner reaction tube 120 corresponds to the source gas and the carrier gas. Due to supply of the source gas into the inner reaction tube 120, the first layer, of which, for example, the thickness is less than that of a mono atomic layer or not more than that of a few atomic layers, is formed on each substrate 10 (on the underfilm of the surface).

(Source Gas Exhaust): S7052

After the first layer is formed on the surface of each substrate 10 due to supply of the source gas into the inner reaction tube 120 through the nozzle 121 for a predetermined time, the supply of the source gas is stopped. In this case, the inner reaction tube 120 is vacuum-exhausted by the vacuum pump (not illustrated), so that the residual unreacted source gas or the residual source gas after contributing to the formation of the first layer inside the inner reaction tube 120 is eliminated from inside the inner reaction tube 120.

In this case, the supply of the carrier gas from the nozzle 121 into the inner reaction tube 120 is retained. The carrier gas acts as purge gas and thus can enhance the effect of eliminating, from inside the inner reaction tube 120, the residual unreacted source gas or the residual source gas after contributing to the formation of the first layer inside the inner reaction tube 120.

(Reactant Gas Supply): S7053

After the residual gas inside the inner reaction tube 120 is removed, with the boat 300 kept rotating due to driving of the rotation drive motor 430, reactant gas is supplied from the nozzle 121 into the inner reaction tube 120 and then the reactant gas having not contributed to reaction is exhausted through the exhaust pipe 130 of the outer reaction tube 110. Thus, the reactant gas is supplied to each substrate 10. Specifically, the flow rate of reactant gas for supply is set in the range 0.2 to 10 slm, more preferably, in the range of 1 to 5 slm.

In this case, the supply of the carrier gas remains stopped. Thus, the carrier gas is prevented from being supplied together with the reactant gas into the inner reaction tube 120. That is, the reactant gas is supplied into the inner reaction tube 120 without being attenuated by the carrier gas, and thus an improvement can be made in the film-forming rate of the first layer. In this case, the temperature of the heater 101 is set so as to be similar to that in the step of supplying source gas.

Similarly to step S7051, the boat elevator 420 including the linear actuator operated based on the process recipe read in step S701 drives the shaft 421 upward/downward to move the boat upward and downward at predetermined time intervals, so that the relative position (height) of the surface of each substrate 10 placed on the boat 300 to the corresponding hole 1210 of the nozzle 121 and the corresponding partition 203 of the partition support 200 is switched between a plurality of positions (e.g., between the position illustrated in FIG. 12B and the position illustrated in FIG. 12C).

In this case, the gas flowing into the inner reaction tube 120 corresponds to the reactant gas. The reactant gas has a substitution reaction to at least part of the first layer formed on each substrate 10 in the step of supplying source gas (S7051), so that a second layer is formed on each substrate 10.

(Residual Gas Exhaust): S7054

After formation of the second layer, the supply of the reactant gas from the nozzle 121 into the inner reaction tube 120 is stopped. Then, along a processing procedure similar to that in step S7052, the residual unreacted reactant gas or the residual reactant gas after contributing to the formation of the second layer and any reaction by-product inside the inner reaction tube 120 are eliminated from inside the inner reaction tube 120.

(Predetermined Number of Times of Performance)

A cycle in which the detailed steps S7051 to S7055 in step S705 are performed in sequence is carried out one or more times (predetermined number of times (n number of times) to form, on each substrate 10, the second layer having a predetermined thickness (e.g., 0.1 to 2 nm). Preferably, the cycle described above is repeated a plurality of times. For example, the cycle is carried out, preferably, 10 to 80 times, more preferably, 10 to 15 times.

As above, the step of supplying source gas (S7051) and the step of supplying reactant gas (S7053) are repeatedly performed with switching between a plurality of positions (e.g., between the position illustrated in FIG. 12B and the position illustrated in FIG. 12C) by upward and downward movements of the boat at predetermined time intervals based on upward/downward driving of the shaft 421 by the boat elevator 420 including the linear actuator operated based on the process recipe read in step S701, so that a thin film having a uniform distribution of film thickness can be formed on the surface of each substrate 10.

Note that, in the above description, given has been the example in which the boat 300 on which the substrates 10 are placed rotates due to the rotation drive motor 430 in the step of supplying source gas (S7051) and in the step of supplying reactant gas (S7053). However, the boat 300 may rotate in the steps of exhausting residual gas (S7052 and S7054).

(After-Purge): S706

After a series of steps in step S705 described above is repeatedly performed a predetermined number of times, N₂ gas serving as inert gas is supplied from the nozzle 121 into the inner reaction tube 120 and then is exhausted through the exhaust pipe 130 of the outer reaction tube 110. The inert gas acts as purge gas and thus purges the inside of the inner reaction tube 120, so that the residual gas and any by-product inside the inner reaction tube 120 are removed from inside the inner reaction tube 120.

(Substrate Unloading): S707

After that, the partition support 200 and the boat 300 are lowered from the inner reaction tube 120 based on the ball screw 411 driven inverse-rotationally due to driving of the upward/downward drive motor 410, followed by transfer of the boat 300 on which the substrates 10 are placed to the housing chamber 500, in which each substrate 10 has its surface on which a thin film having a predetermined thickness is formed.

The substrates 10, each having the thin film formed thereon, on the boat 300 in the housing chamber 500 are taken outward from the housing chamber 500 through the substrate access port 310, followed by termination of the processing to the substrates 10.

Examples of the source gas that can be used include chlorosilane-based gases, such as monochlorosilane (SiH₃Cl, abbreviation: MCS) gas, dichlorosilane (SiH₂Cl₂, abbreviation: DCS) gas, trichlorosilane (SiHCl₃, abbreviation: TCS) gas, tetrachlorosilane (SiCl₄, abbreviation: STC) gas, hexachlorodisilane (Si₂Cl₆, abbreviation: HCDS) gas, and octachlorotrisilane (Si₃Cl₈, abbreviation: OCTS) gas. Further examples of the source gas that can be used include fluorosilane-based gases, such as tetrafluorosilane (SiF₄) gas and difluorosilane (SiH₂F₂) gas, bromosilane-based gases, such as tetrabromosilane (SiBr₄) gas and dibromosilane (SiH₂Br₂) gas, and iodosilane-based gases, such as tetraiodosilane (Silo) gas and diiodosilane (SiH₂I₂) gas. Further examples of the source gas that can be used include am inosilane-based gases, such as tetrakis(dimethylamino)silane (Si[N(CH₃)_{2]4}, abbreviation: 4DMAS) gas, tris(dimethylamino)silane (Si[N(CH₃)_{2]3}H, abbreviation: 3DMAS) gas, bis(diethylamino)silane (Si[N(C₂H₅)_{2]2}H₂, abbreviation: BDEAS) gas, and bis(tertiary butylamino)silane (SiH₂[NH(C₄H₉)]₂, abbreviation: BTBAS) gas. From among these gases, one or more gases can be used as the source gas.

Examples of the reactant gas that can be used include oxygen (O₂), ozone (O₃), and water (H₂O).

Examples of the carrier gas (inert gas) that can be used include rare gases, such as nitrogen (N₂) gas, argon (Ar) gas, helium (He) gas, neon (Ne) gas, and xenon (Xe) gas.

According to the examples described above, for example, a silicon nitride (Si₃N₄) film, a silicon dioxide (SiO₂) film, or titanium nitride (TiN) film can be formed on each substrate 10. However, such films are not limiting. For example, a single-element film of W, Ta, Ru, Mo, Zr, Hf, Al, Si, Ge, Ga, or an element homologous with those elements, a compound film of nitrogen and any of the elements (nitride film), or a compound film of oxygen and any of the elements (oxide film) can be achieved. Note that, for formation of such films, a halogen-containing gas or gas containing at least any of the element of halogen, an amino group, a cyclopenta group, oxygen (O), carbon (C), and an alkyl group can be used.

According to the present first embodiment, in accordance with the surface area of each substrate 10 or the type of a film to be formed, film forming can be performed with a change in the positional relationship between each substrate 10 and the corresponding hole 1210 of the nozzle 121 for supplying film-forming gas, based on the previously set condition, so that an improvement can be made in the in-plane uniformity of the distribution of film thickness of a thin film to be formed on each substrate 10 placed on the boat 300.

The film-forming process has been described as an applied example of the present disclosure, but the present disclosure is not limited to this and thus can be applied to an etching process.

In a case where the present disclosure is applied to an etching process, with a narrow interval between each substrate 10 and the upper partition 203 to the substrate (the state in FIG. 12B) due to the shaft 421 driven upward/downward based on the operation of the boat elevator 420 including the linear actuator, etching gas is supplied, enabling E processing in depo-etch-depo (DED) processing. The DED processing corresponds to processing in which film-forming processing and etching processing are repeatedly performed to form a predetermined film. The E processing described above corresponds to etching processing.

During supply of the etching gas, the interval between each substrate 10 and the upper partition 203 to the substrate 10 is widened (the state in FIG. 12C), enabling regulation of the substrate in-plane uniformity of etching.

In the present disclosure, examples of parameters for regulation of the interval between each substrate 10 and the upper partition 203 to the substrate 10 include the distribution of film thickness, temperature, gas flow rate, pressure, time, the type of gas, and the surface area of a substrate. In a case where information on the distribution of film thickness is used as a parameter, a film-thickness measurer is provided inside the substrate processing apparatus, and the interval between each substrate 10 and the upper partition 203 to the substrate 10 is changed based on a result of film-thickness measurement.

Alternatively, the amount of decomposition of gas may be detected by a sensor, and then the interval between each substrate 10 and the upper partition 203 to the substrate may be changed based on data of the amount of decomposition.

### Second Embodiment of the Present Disclosure

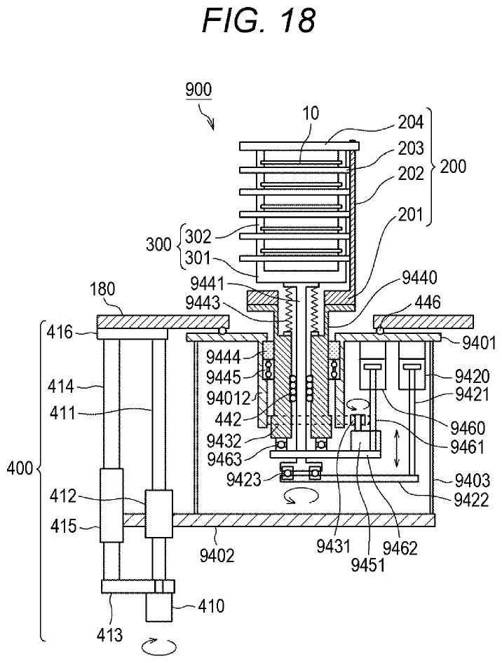

FIG. 18 illustrates the configuration of a substrate processing apparatus 900 according to a second embodiment of the present disclosure. Constituents the same as those in the first embodiment are denoted with the same numbers and thus descriptions thereof will be omitted. Note that, in the second embodiment, a heater 101, an outer reaction tube 110, an inner reaction tube 120, a gas supply nozzle 121, a manifold 111, an exhaust pipe 130, and a controller 260 are identical in configuration to those in the first embodiment and thus are not illustrated in FIG. 18.

The present second embodiment is the same as the first embodiment in that an upward/downward movement driver 400 drives a partition support 200 and a substrate support (boat) 300 upward/downward between the inner reaction tube 120 and a housing chamber 500, in that a rotation drive motor 9451 drives a support 9440 rotationally to drive the partition support 200 and the substrate support 300 rotationally around the center of substrates 10 supported by the substrate support 300, and in that a boat elevator 9420 including a linear actuator drives a plate 9422 upward/downward through a shaft 9421 to drive a support 9441 fixed to the boat 300 relatively upward/downward to the support 9440 fixed to the partition support 200.

The substrate processing apparatus 900 according to the present second embodiment is different in configuration from the substrate processing apparatus 100 described in the first embodiment in that the respective heights of the partition support 200 and the substrate support 300 can be regulated independently with a base flange 9401 pressed against a chamber 180 through an O-ring 446 after the upward/downward movement driver 400 raises the partition support 200 and the substrate support 300.

That is, as illustrated in FIG. 18, the substrate processing apparatus 900 according to the present second embodiment includes a boat elevator 9460 including a second linear actuator that moves the partition support 200 upward or downward independently of the substrate support 300. The boat elevator 9460 including the second linear actuator drives a plate 9462 upward/downward through a shaft 9461 to move the partition support 200 upward or downward independently of the substrate support 300.

The plate 9462 is connected, through a rotation sealer 9463, to the support 9440 supporting the partition support 200 through a base 201.

The boat elevator 9420 including the linear actuator and the boat elevator 9460 including the second linear actuator are fixed to the base flange 9401 supported to a base plate 9402 through a side plate 9403.

The rotation drive motor 9451 is attached to the plate 9462 that the boat elevator 9460 including the second linear actuator drives upward/downward.

The rotation drive motor 9451 has a leading end portion to which a gear 9431 is attached and drives a rotation transmission belt 9432 engaged with the gear 9431, so that the support 9440 engaged with the rotation transmission belt 9432 is driven rotationally. The support 9440 supporting the partition support 200 through the base 201 is driven by the rotation drive motor 9451 through the rotation transmission belt 9432 to rotate the partition support 200 and the boat 300.

The configuration of the substrate processing apparatus 900 according to the present second embodiment enables, independently, regulation of the positions in the height direction of the substrates 10 placed on the boat 300 to holes 1210 of the nozzle 121 and regulation of the positions in the height direction of partitions 203 fixed to the partition support 200 to the holes 1210 of the nozzle 121.

Thus, according to the present second embodiment, in accordance with the surface area of each substrate 10 or the type of a film to be formed, film forming can be performed with, independently, regulation of the positions in the height direction of the substrates 10 placed on the boat 300 to the holes 1210 of the nozzle 121 and regulation of the positions in the height direction of the partitions 203 fixed to the partition support 200 to the holes 1210 of the nozzle 121, so that an improvement can be made in the in-plane uniformity of the distribution of film thickness of a thin film to be formed on each substrate 10 placed on the boat 300.

### Third Embodiment of the Present Disclosure

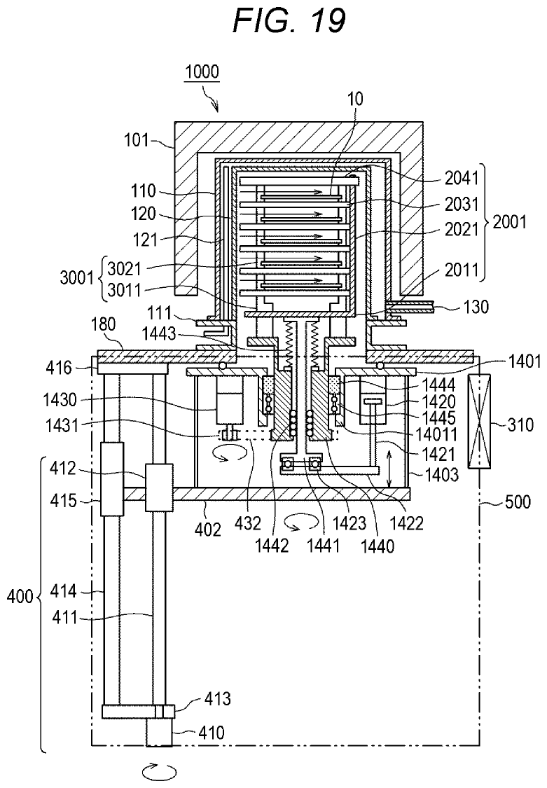

FIG. 19 illustrates the configuration of a substrate processing apparatus 1000 according to a third embodiment of the present disclosure. Constituents the same as those in the first embodiment are denoted with the same numbers and thus descriptions thereof will be omitted.

The substrate processing apparatus 1000 according to the present embodiment is different in configuration from the substrate processing apparatus 100 described in the first embodiment in that a substrate support (boat) 3001 is moved upward or downward independently of a partition support 2001 as opposed to the first embodiment.

The present third embodiment is the same as the first embodiment in that an upward/downward movement driver 400 drives the partition support 2001 and the substrate support 3001 upward/downward between an inner reaction tube 120 and a housing chamber 500 and drives the partition support 2001 and the substrate support 3001 rotationally around the center of substrates 10 supported by the substrate support 3001 and in that a boat elevator 1420 including a linear actuator drives a plate 1422 upward/downward through a shaft 1421 to drive a support 1440 fixed to the boat 3001 upward/downward relative to a support 1441 fixed to the partition support 2001.

In the present third embodiment, the boat elevator 1420 including the linear actuator moves the substrate support 3001 upward or downward independently of the partition support 2001.

The boat elevator 1420 including the linear actuator drives the shaft 1421 upward/downward. The shaft 1421 has a leading end portion to which the plate 1422 is attached. The plate 1422 is connected, through a bearing 1423, to the support 1441 fixed to the partition support 2001.

Meanwhile, the support 1441 is supported by the support 1440 through a linear guide bearing 1442. The support 1440 has an upper face connected to a base 3011 of the substrate support 3001. Between the support 1440 and an inner portion 14011 of the barrel of a base flange 1401, a vacuum seal 1444 is interposed. The vacuum seal 1444 has a lower portion guided rotatably by a bearing 1445 with respect to the inner portion 14011 of the barrel of the base flange 1401.

According to such a configuration, when the boat elevator 1420 including the linear actuator drives the shaft 1421 upward/downward, partitions 2031 fixed to the partition support 2001 can be driven upward/downward relative to the support 1441 fixed to the boat 3001.

Since the support 1441 is connected to the plate 1422 through the bearing 1423, the partition support 2001 can rotate together with the boat 3001 when a rotation drive motor 1430 drives the boat 3001 rotationally.

A vacuum bellows 1443 is interposed as a connection between the support 1441 fixed to the partition support 2001 and the support 1440 fixed to the boat 3001.

The configuration of the substrate processing apparatus 1000 according to the present third embodiment enables regulation of the positions in the height direction of the partitions 2031 fixed to the partition support 2001 to holes 1210 of a nozzle 121 with the positions of the substrates 10 placed on the boat 3001 kept constant (fixed).

Thus, according to the present third embodiment, in accordance with the surface area of each substrate 10 or the type of a film to be formed, film forming can be performed with a change, based on a previously set condition, in the positional relationship between the partitions 2031 covering the upper face and lower face of each substrate 10 and the corresponding hole 1210 of the nozzle 121 for supplying film-forming gas, so that an improvement can be made in the in-plane uniformity of the distribution of film thickness of a thin film to be formed on each substrate 10 placed on the boat 3001.

### Fourth Embodiment of the Present Disclosure

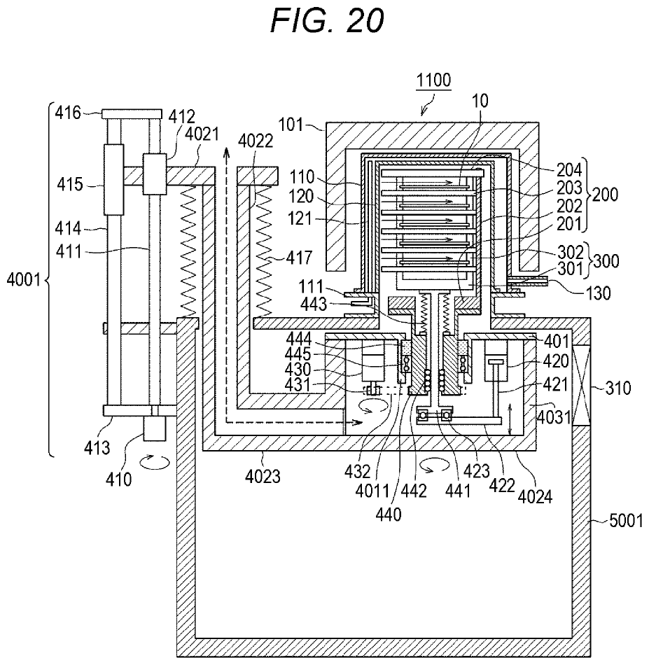

FIG. 20 illustrates the configuration of a substrate processing apparatus 1100 according to a fourth embodiment of the present disclosure. Constituents the same as those in the first embodiment are denoted with the same numbers and thus descriptions thereof will be omitted.

The substrate processing apparatus 1100 according to the present fourth embodiment has a structure in which a housing chamber 5001 can be vacuum-exhausted with a vacuum exhauster (not illustrated), in contrast to the substrate processing apparatus 100 described in the first embodiment. Thus, without such vacuum sealing with the O-ring 446 between the outer reaction tube 110 and the housing chamber 500 as described with FIG. 2 in the first embodiment, a change can be made in the height of a base flange 401 during substrate processing.

As a result, in the present fourth embodiment, not only a change can be made in the height of a substrate support 300 with respect to a partition support 200 during processing to substrates 10, as described in the first embodiment, but also simultaneous changes can be made in the respective positions in the height direction of the substrate support 300 and the partition support 200 to holes 1210 of a gas supply nozzle 121.

Constituents the same as those described with FIGS. 1 and 2 in the first embodiment are denoted with the same numbers and thus descriptions thereof will be omitted.

In the present fourth embodiment, as illustrated in FIG. 20, an upward/downward movement driver 4001 is disposed outside the housing chamber 5001, and a vacuum bellows 417 is interposed as a connection between a plate 4021 fixed to the upward/downward movement driver 4001 and displaceable upward/downward by the upward/downward movement driver 4001 and the housing chamber 5001, leading to vacuum sealing with the housing chamber 5001 having its inside hermetically sealed.

That is, with a structure in which, with a base flange 401 and a plate 4024 between which the space is covered with a side wall 4031, the internal airtightness can be secured to the housing chamber 5001, the inside of the housing chamber 5001 can be kept in a vacuum state with the space surrounded by the base flange 401, the plate 4024, and the side wall 4031 kept at atmospheric pressure through pipes 4023 and 4022 extending from the side wall 4031.

With the space between the base flange 401 and the plate 4024 covered with the side wall 4031, connection for electric wiring of a lifter/rotator or connection for cooling water for vacuum seal protection (not illustrated) can be established.

According to the present fourth embodiment, not only a change can be made in the height of the substrate support 300 with respect to the partition support 200 during processing to the substrates 10, but also simultaneous changes can be made in the respective positions in the height direction of the substrate support 300 and the partition support 200 to the holes 1210 of the gas supply nozzle 121. Thus, during processing to the substrates 10, control of the heights of partitions 203 fixed to the partition support 200 and control of the heights of the substrates 10 placed on the substrate support 300 can be individually performed to the holes 1210 of the gas supply nozzle 121.

Thus, according to the present embodiment, an improvement can be made in the in-plane uniformity of the distribution of film thickness of a thin film to be formed on each substrate 10 placed on the boat 300.

As described above, according to the present disclosure, provided can be a method of forming a uniform film on each substrate with a change in the positional relationship between the substrates and the nozzle for supplying film-forming gas in accordance with the surface area of each substrate and the type of a film to be formed.

Furthermore, according to the present disclosure, the nozzle for supplying film-forming gas is fixed to the reaction chamber, and the upward/downward movement driver moves, upward or downward, the substrate support (boat) on which substrates are placed on a multiple-stage basis. For gas blocking or pressure blocking between the reaction chamber for film-forming processing and the housing chamber located below the reaction chamber, carried out are O-ring sealing and sealing based on a stretchable sealing structure (bellows) corresponding to the stoke of upward/downward operation of the substrate support (change in the positional relationship with the nozzle). On the other hand, in a case where the loading area (inside the housing chamber 500) has a pressure equivalent to that inside the inner reaction tube 120, the reaction chamber and the vacuum loading area (inside the housing chamber 500) are in communication without O-ring sealing. In this case, with supply of inert gas from the vacuum loading area, gas blocking is performed with pressure gradient.

In addition, according to the present disclosure, rotation of the substrates during film forming enables supply of film-forming gas injected from the nozzle for supplying film-forming gas with a change in gas flow velocity on the outer layer of each wafer based on regulation between a position closer to and a position distant from the surface of each substrate, so that the decomposition state until the film-forming gas that tends to have a gas phase reaction easily contributes to film forming after reaching the outer layer of each wafer can be regulated.

According to the present disclosure described above, provided is a method of manufacturing a semiconductor device, the method including: driving a substrate support holding a plurality of substrates at intervals in superposition in the up-down direction, by an upward/downward movement driver, to house the substrate support into a reaction tube; heating the substrates held on the substrate support housed inside the reaction tube by a heater disposed surrounding the periphery of the reaction tube; and repeating supplying source gas from a plurality of holes of a gas supply nozzle to the substrates held by the substrate support housed inside the reaction tube, exhausting the supplied source gas from the reaction tube, supplying reactant gas from the plurality of holes of the gas supply nozzle to the substrates, and exhausting the supplied reactant gas from the reaction tube, to form a thin film onto each of the plurality of substrates, in which the supplying the source gas from the plurality of holes of the gas supply nozzle and the supplying the reactant gas from the plurality of holes of the gas supply nozzle are performed with the positional (height) relationship between the plurality of substrates held by the substrate support and the plurality of holes of the gas supply nozzle, regulated in accordance with a previously set condition due to control of the height of the substrate support housed in the reaction tube by an upward/downward driver.

In addition, according to the present disclosure, the source gas and the reactant gas are supplied from the plurality of holes of the gas supply nozzle, of which the interval is identical to the interval in the up-down direction between the plurality of substrates held by the substrate support.

Furthermore, according to the present disclosure, the supplying the source gas from the plurality of holes of the gas supply nozzle and the supplying the reactant gas from the plurality of holes of the gas supply nozzle are repeatedly performed with a change in the positional (height) relationship between the plurality of substrates held by the substrate support and the plurality of holes of the gas supply nozzle due to control of the height of the substrate support housed in the reaction tube by the upward/downward movement driver.

According to the present disclosure, in simultaneous processing to a plurality of substrates, the distribution of concentration of gas on each substrate can be controlled, so that an improvement can be made in the uniformity of thickness of a film to be formed on each substrate.

In addition, according to the present disclosure, in simultaneous processing to a plurality of substrates, the substrates are processed with control of the distribution of concentration of gas on each substrate, so that an improvement can be made in the efficiency of supply of material gas, such as source gas or reactant gas, leading to a reduction in cost with a reduced waste of material gas.

In addition, according to the present disclosure, a plurality of partitions of a partition support of a substrate holder is each provided with a cut-away portion for disposition of a first prop of a substrate support, in order to prevent interference between the substrate support and the partition. Thus, with a small cross section of the gas flow path between the upper and lower sides of each partition, the distribution of concentration of gas on each substrate can be controlled accurately.

What is claimed is:

1. A substrate holder comprising:
a substrate support including a plurality of first props capable of supporting a plurality of substrates at intervals in an up-down direction; and
a partition support including a plurality of partitions and a plurality of second props, the plurality of partitions each having a cut-away portion at which the plurality of first props is disposed, the plurality of partitions being disposed one-to-one in spaces between the plurality of substrates held by the substrate support, the plurality of second props supporting the plurality of partitions.

2. The substrate holder according to claim 1, wherein
the plurality of first props each includes a support that supports the plurality of substrates, and
the cut-away portion is provided such that the support is movable in the up-down direction.

3. The substrate holder according to claim 1, wherein
a gap is present between each of the plurality of partitions and each of the plurality of first props.

4. The substrate holder according to claim 3, wherein
the gap is 2 to 4 mm.

5. The substrate holder according to claim 1, wherein
the plurality of first props each includes a support that supports the plurality of substrates, and
the cut-away portion includes a first recess capable of housing the support.

6. The substrate holder according to claim 1, wherein
the plurality of first props is movable upward or downward such that the plurality of substrates moves to a height.

7. The substrate holder according to claim 1, wherein
the substrate support includes a base supporting the plurality of first props at respective lower ends of the plurality of first props, and
the base is movable upward or downward by an upward/downward mover.

8. The substrate holder according to claim 1, further comprising a cover that covers a heat insulator, wherein
the cover includes a second recess at which the plurality of first props is disposed.

9. The substrate holder according to claim 1, further comprising a cover that covers a heat insulator, wherein
the cover includes a second recess at which the plurality of first props is disposed,
the substrate support includes a base supporting the plurality of first props at respective lower ends of the plurality of first props, the base being movable upward or downward by an upward/downward mover, and
the second recess has a lower portion provided with an opening in which the base is disposed.

10. The substrate holder according to claim 9, wherein
the opening is wider by 1 to 10 mm than a range in which the base is movable.

11. The substrate holder according to claim 8, wherein
part of each of the plurality of first props is opposite the cover,
at least a portion facing the cover in the part is columnar in shape, and
the second recess has a shape in which the portion columnar in shape is disposed.

12. A substrate processing apparatus comprising:
a substrate holder including: a substrate support including a plurality of first props capable of supporting a plurality of substrates at intervals in an up-down direction; and a partition support including a plurality of partitions and a plurality of second props, the plurality of partitions each having a cut-away portion at which the plurality of first props is disposed, the plurality of partitions being disposed one-to-one in spaces between the plurality of substrates held by the substrate support, the plurality of second props supporting the plurality of partitions;
a reaction tube configured to house the substrate holder; and
a gas supplier configured to supply gas into the reaction tube.

13. The substrate processing apparatus according to claim 12, wherein
the plurality of first props each includes a support that supports the plurality of substrates, and
the cut-away portion is provided such that the support is movable in the up-down direction.

14. The substrate processing apparatus according to claim 12, wherein
a gap is present between each of the plurality of partitions and each of the plurality of first props.

15. The substrate processing apparatus according to claim 12, wherein
the plurality of first props each includes a support that supports the plurality of substrates, and
the cut-away portion includes a first recess capable of housing the support.

16. The substrate processing apparatus according to claim 12, wherein
the plurality of first props is movable upward or downward such that the plurality of substrates moves to a height.

17. The substrate processing apparatus according to claim 12, further comprising an upward/downward mover, wherein
the substrate support includes a base supporting the plurality of first props at respective lower ends of the plurality of first props, and
the base is movable upward or downward by the upward/downward mover.

18. The substrate processing apparatus according to claim 12, further comprising a cover that covers a heat insulator, wherein
the cover includes a second recess at which the plurality of first props is disposed.

19. A method of manufacturing a semiconductor device by use of a substrate processing apparatus including: a substrate holder including: a substrate support including a plurality of first props capable of supporting a plurality of substrates at intervals in an up-down direction; and a partition support including a plurality of partitions and a plurality of second props, the plurality of partitions each having a cut-away portion at which the plurality of first props is disposed, the plurality of partitions being disposed one-to-one in spaces between the plurality of substrates held by the substrate support, the plurality of second props supporting the plurality of partitions; a reaction tube configured to house the substrate holder; and a gas supplier configured to supply gas into the reaction tube, the method comprising:
loading the substrate holder into the reaction tube; and
supplying the gas into the reaction tube.

20. A non-transitory computer-readable recording medium storing a program that causes, by a computer, the substrate processing apparatus to perform a process comprising the method according to claim 19.
